(19) United States
(12) Patent Application Publication
(10) Pub. No.: US 2003/0113980 A1
(43) Pub. Date: Jun. 19, 2003

(54) Method for manufacturing and structure of semiconductor assembly with a shallow trench device region

(75) Inventor: Jeffrey A. Babcock, Richardson, TX (US)

Correspondence Address: TEXAS INSTRUMENTS INCORPORATED, P O BOX 655474, M/S 3999, DALLAS, TX, 75265

(73) Assignee: Texas Instruments Incorporated

(21) Appl. No.: 10/025,580

(22) Filed: Dec. 18, 2001

(51) Int. Cl. H01L 21/76

(52) U.S. Cl. 438/424

(57) ABSTRACT

A method for manufacturing a semiconductor assembly includes forming an active region of a semiconductor substrate and removing at least part of the active region to form a shallow trench opening. The method also includes forming a dielectric layer proximate the active region at least partially within the shallow trench opening and removing at least part of the dielectric layer to form a first device region. The method may include forming a first semiconductor device at the first device region. The first semiconductor device may be operable to facilitate the flow of electric current through the assembly The method may also include forming a second semiconductor device at a second device region, wherein a depth of an area of the active region below the second device region is greater than a depth of an area of the active region below the first device region.

### RELATED APPLICATIONS

This application is related to Provisional Application Serial Number ______, entitled “Method for Manufacturing and Structure of Semiconductor Device with Shallow Trench Collector Contact Region,” filed on Oct. 1, 2001.

### TECHNICAL FIELD OF THE INVENTION

This invention relates generally to semiconductor assemblies and, more specifically, to a semiconductor assembly with a shallow trench device region and a method of manufacturing the same.

### BACKGROUND OF THE INVENTION

Different semiconductor devices can have many different characteristics depending on how the semiconductor devices are manufactured. For example, one particular semiconductor device may have a higher speed and be more suitable for digital applications than another semiconductor device. Furthermore, many applications for semiconductor technology utilize multiple chips containing devices with different characteristics. The manufacture of multiple chips for a particular application can be both time consuming and costly to a manufacturer.

### SUMMARY OF THE INVENTION

The present invention provides a semiconductor assembly and method for manufacturing the same that substantially eliminates or reduces at least some of the disadvantages and problems associated with previously developed semiconductor assemblies and methods for manufacturing the same.

In accordance with a particular embodiment of the present invention, a method for manufacturing a semiconductor assembly includes forming an active region of a semiconductor substrate and removing at least part of the active region to form a shallow trench opening. The method also includes forming a dielectric layer proximate the active region at least partially within the shallow trench opening and removing at least part of the dielectric layer to form a first device region. The method may include forming a first semiconductor device at the first device region. The first semiconductor device may be operable to facilitate the flow of electric current through the assembly The method may also include forming a second semiconductor device at a second device region, wherein a depth of an area of the active region below the second device region is greater than a depth of an area of the active region below the first device region.

In accordance with another embodiment, a semiconductor assembly includes an active region of a semiconductor substrate and a shallow trench isolation structure adjacent at least a portion of the active region. The assembly also includes a first device region adjacent at least a portion of the shallow trench isolation structure. The first device region has a depth approximately equal to a depth of the shallow trench isolation structure. The assembly may include a first semiconductor device at the first device region. The first semiconductor device may be operable to facilitate the flow of electric current through the assembly. The assembly may also include a second semiconductor device at a second device region wherein a depth of an area of the active region below the second device region is greater than a depth of an area of the active region below the first device region.

Technical advantages of particular embodiments of the present invention include a method of manufacturing a semiconductor assembly utilizing shallow trench isolation to form a first device region and a first semiconductor device at the first device region. A second semiconductor device is formed at a second device region of the assembly. Such a method allows a manufacturer produce a semiconductor assembly having multiple semiconductor devices, each with different characteristics. Using the method, single chip solutions may be possible where dual chips were previously needed. Accordingly, the total time and expense associated with manufacturing semiconductor technology for a particular application are reduced.

Other technical advantages will be readily apparent to one skilled in the art from the following figures, descriptions and claims. Moreover, while specific advantages have been enumerated above, various embodiments may include all, some or none of the enumerated advantages.

### BRIEF DESCRIPTION OF THE DRAWINGS

For a more complete understanding of the particular embodiments of the invention and their advantages, reference is now made to the following descriptions, taken in conjunction with the accompanying drawings, in which:

FIG. 1 is a cross-sectional diagram illustrating a semiconductor assembly with first and second device regions at one stage of a manufacturing process, in accordance with a particular embodiment of the present invention;

FIG. 2 is a cross-sectional diagram illustrating a semiconductor assembly with an active region and an oxide layer at one stage of a manufacturing process, in accordance with a particular embodiment of the present invention;

FIG. 3 is a cross-sectional diagram illustrating the semiconductor assembly of FIG. 2 at another stage of a manufacturing process showing openings for shallow trench isolation structures and semiconductor devices, in accordance with a particular embodiment of the present invention;

FIG. 4 is a cross-sectional diagram illustrating the semiconductor assembly of FIG. 3 with a dielectric layer and photoresist at another stage of a manufacturing process, in accordance with a particular embodiment of the present invention;

FIG. 5 is a cross-sectional diagram illustrating the semiconductor assembly of FIG. 4 with first and second device regions at another stage of a manufacturing process, in accordance with a particular embodiment of the present invention;

FIG. 6 is a cross-sectional diagram illustrating the semiconductor assembly of FIG. 5 with first and second semiconductor devices at another stage of a manufacturing process, in accordance with a particular embodiment of the present invention; and

FIG. 7 is a cross-sectional diagram illustrating a semiconductor assembly with first and second device regions and bipolar technology at one stage of a manufacturing process, in accordance with a particular embodiment of the present invention.

### DETAILED DESCRIPTION OF THE INVENTION

FIG. 1 illustrates a semiconductor assembly 10 at one stage of a manufacturing process, in accordance with an embodiment of the present invention. Semiconductor assembly 10 includes a first device region 26 formed using methods of the present invention. First device region 26 is formed between shallow trench isolation structures 24. First device region 26 provides an area in which a first semiconductor device may be subsequently formed. A second semiconductor device may be formed at a second device region 27. The semiconductor devices subsequently formed at first and second device regions 26 and 27, respectively, will have different characteristics, including different speeds, voltages, capacitances and power. By manufacturing a semiconductor assembly 10 having semiconductor devices with different characteristics, a single chip may be utilized for a particular application that would otherwise require more than one chip.

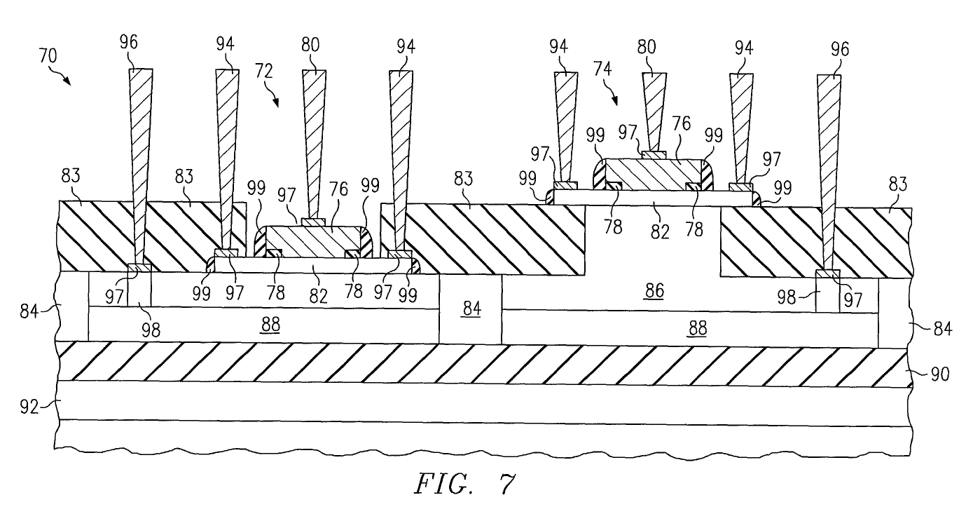

In this embodiment, semiconductor assembly 10 is illustrated incorporating metal oxide semiconductor field effect transistor (MOSFET) technology; however, other embodiments of the present invention may incorporate other semiconductor device technologies, such as bipolar technology as illustrated in FIG. 7.

Semiconductor assembly 10 includes semiconductor substrate 11 which comprises a wafer 13. As discussed in greater detail below, in this embodiment semiconductor substrate 11 also includes an oxide layer 14. An active region 18 is disposed adjacent oxide layer 14. Deep trench isolation structures 20 are adjacent active region 18.

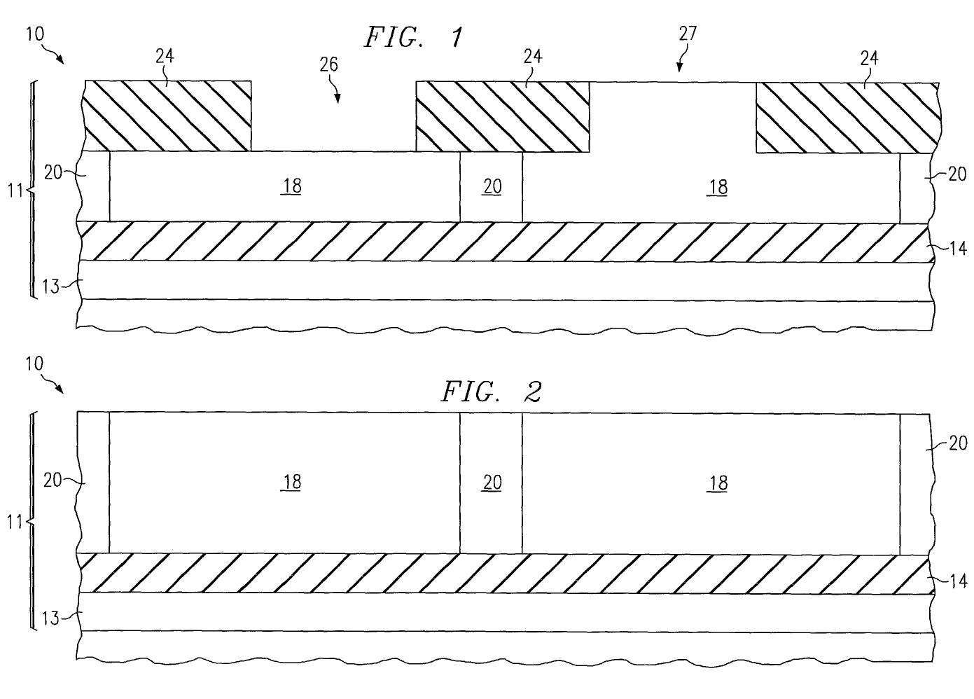

FIG. 2 illustrates a semiconductor assembly 10 at one stage of a manufacturing process, in accordance with an embodiment of the present invention. Semiconductor substrate 11 comprises wafer 13, which is formed from a single crystalline silicon material. Semiconductor substrate 11 may comprise other suitable materials or layers without departing from the scope of the present invention. For example, semiconductor substrate 11 may include a recrystallized semiconductor material, a polycrystalline semiconductor material or any other suitable semiconductor material.

Semiconductor assembly 10 includes oxide layer 14. Oxide layer 14 may be formed by any of a variety of techniques known to those skilled in the art and may comprise any suitable oxide. Other embodiments of the present invention may not include an oxide layer or may include one or more layers in place of oxide layer 14 comprising other materials, such as glass.

Active region 18 is formed within semiconductor substrate 11. In this embodiment, active region 18 is a well region. Active region 18 is a positively-doped well region (“P-well”); however, in other embodiments, active region 18 may be a negatively-doped well region (“N-well”). In other embodiments, active region 18 may also be a deep N-type or a deep P-type region. Active region 18 may be formed by any of a variety of techniques known to those skilled in the art, such as high energy implantation and/or diffusion.

In the illustrated embodiment, deep trench isolation structures 20 are formed adjacent active region 18. Deep trench isolation structures 20 provide isolation between elements of semiconductor assembly 10 during use of semiconductor assembly 10. Other embodiments of the present invention may or may not include deep trench isolation structures 20 or may provide isolation between elements of a semiconductor assembly in other ways, such as through diffusion.

Deep trench isolation structures 20 may be formed using photoresist and etching. Other means known to those of ordinary skill in the art may also be used to form deep trench isolation structures 20. Deep trench isolation structures 20 may be filled with a suitable semiconductive material such as intrinsic polycrystalline silicon or a suitable insulative material such as silicon dioxide. Such material may be deposited within deep trench isolation structures 20 using a suitable deposition process such as chemical vapor deposition. Deep trench isolation structures may include a liner oxide formed around at least some of the edges of deep trench isolation structures 20 in accordance with techniques known to those of ordinary skill in the art.

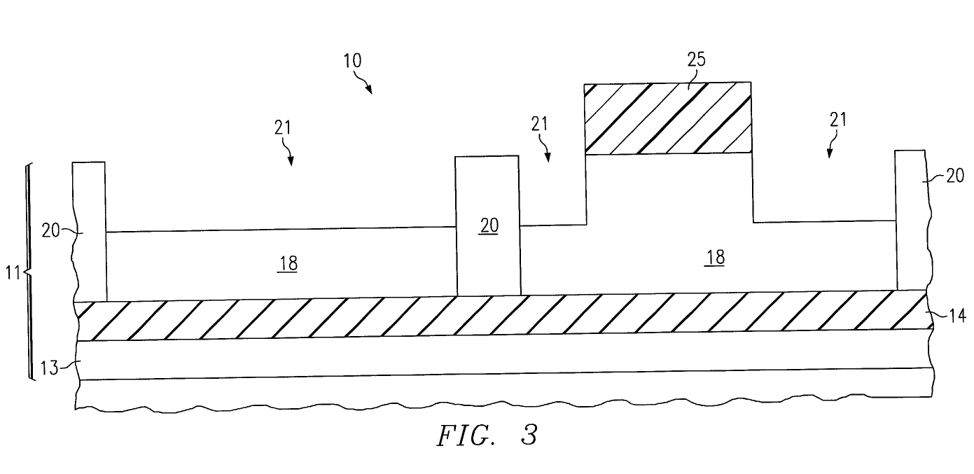

FIG. 3 illustrates semiconductor assembly 10 of FIG. 2 at a further stage in the manufacturing process. Openings 21 have been formed through a masking and etching process. A portion of active region 18 is covered with photoresist 25 so that other portions of active region 18 may be etched away to form openings 21. Openings 21 provide a location for subsequent formation of shallow trench isolation structures and semiconductor devices, discussed in greater detail below.

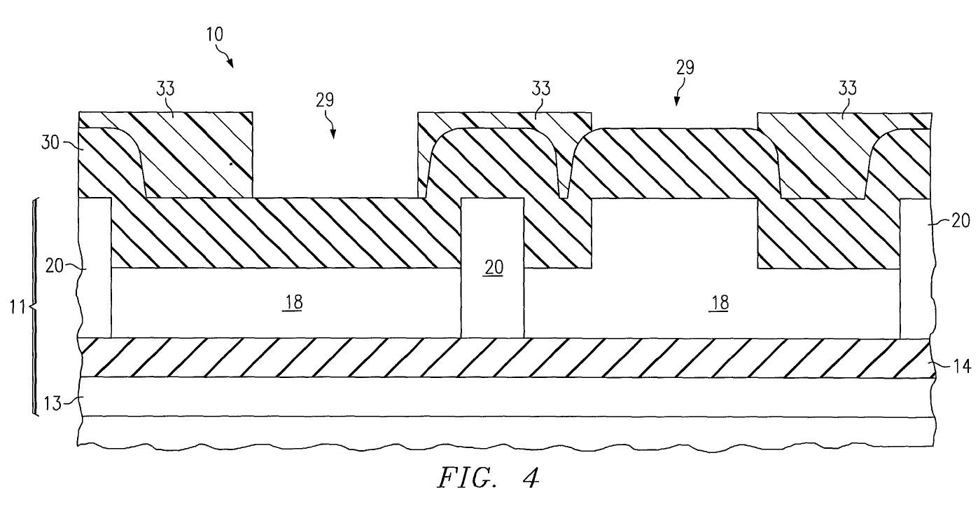

FIG. 4 illustrates semiconductor assembly 10 of FIG. 3 at a further stage in the manufacturing process. Dielectric layer 30 is formed adjacent active region 18. Dielectric layer 30 may comprise any suitable dielectric, such as tetraethyl orthosilicate (TEOS) or borophosphosilicate glass (BPSG). Dielectric layer 30 may also comprise a material with a low dielectric coefficient. Dielectric layer 30 may be formed by any of a variety of techniques known to those of ordinary skill in the art. Semiconductor assembly 10 may also include other layers, such as a liner oxide formed prior to the formation of dielectric layer 30. Such liner oxide may have a thickness on the order of ten nanometers.

A photoresist is formed adjacent dielectric layer 30. A reverse shallow trench isolation (“RSTI”) mask is used to cover the photoresist in all areas except areas 29, both above active region 18, where semiconductor devices will be formed later in the manufacturing process. The photoresist is then exposed to a solvent which removes portions of the photoresist not covered by the RSTI mask, leaving photoresist 33 adjacent dielectric layer 30.

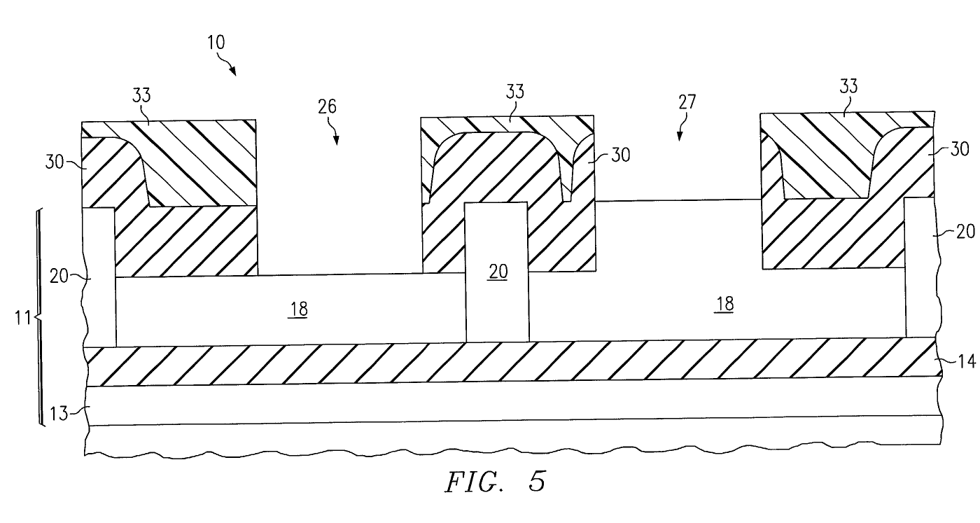

FIG. 5 illustrates semiconductor assembly 10 of FIG. 4 at a further stage in the manufacturing process. First device region 26 and second device region 27 have been formed. An etchant, plasma or other material is used to react with the areas of dielectric layer 30 of FIG. 4 which were not covered by photoresist 33. Such areas of dielectric layer 30 are etched away leaving first and second device regions 26 and 27, respectively, where semiconductor devices will be subsequently formed. First device region 26 may have a depth of approximately 3,000 to 10,000 angstroms.

Referring back to FIG. 1, semiconductor assembly 10 of FIG. 5 is illustrated at a further stage in the manufacturing process. Photoresist 33 of FIG. 5 has been removed. Portions of dielectric layer 30 have been grinded away using a chemical, mechanical polishing method in accordance with techniques known to those skilled in the art, leaving shallow trench isolation structures 24.

Shallow trench isolation structures 24 are adjacent portions of active region 18. Shallow trench isolation structures 24 may provide isolation between active regions of semiconductor assembly 10. Shallow trench isolation structures 24 may have a depth of approximately 3,000 to 10,000 angstroms. The depth of shallow trench isolation structures 24 may also be equal to the depth of first device region 26 due to the formation process of shallow trench isolation structures 24.

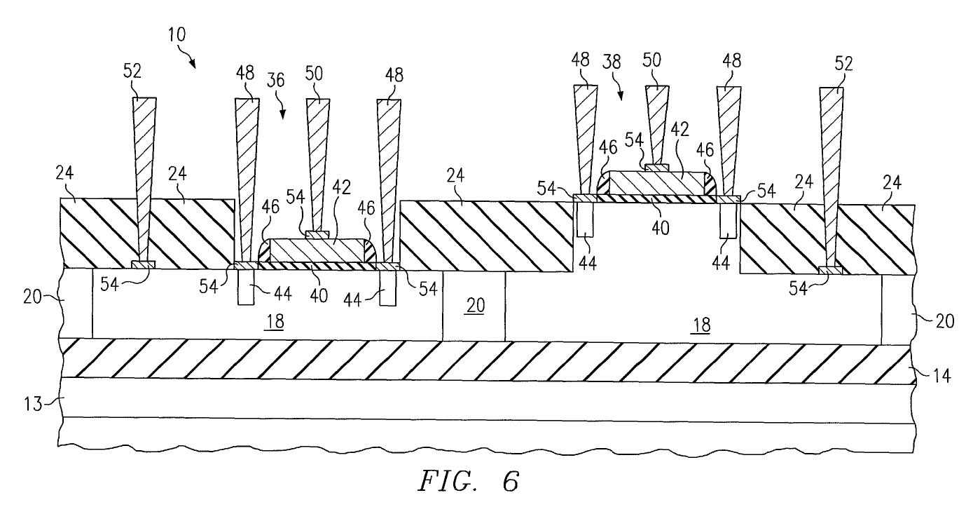

FIG. 6 illustrates semiconductor assembly 10 of FIG. 1 at a further stage in the manufacturing process. FIG. 6 shows a first semiconductor device 36 formed within first device region 26 of FIG. 1. A second semiconductor device 38 is formed at second device region 27 of FIG. 1. First and second semiconductor devices 36 and 38, respectively, each include a gate dielectric 40, a gate electrode 42, source/drain regions 44, source/drain contacts 48 and a gate contact 50. Semiconductor devices formed within device regions in other embodiments may not include all of the components of semiconductor devices 36 and 38 listed above. Other embodiments of the present invention may also include semiconductor devices having other components formed within device regions, as discussed below with regard to FIG. 7.

Forming first semiconductor device 36 within first device region 26 of FIG. 1 and second semiconductor device 38 at second device region 27 of FIG. 1 will provide semiconductor assembly 10 with dual semiconductor devices having different characteristics. For example, because the depth of active region 18 below first semiconductor device 36 is smaller than the depth of active region 18 below second semiconductor device 38, the area of active region 18 below first semiconductor device 36 may be more depleted of charge than the area of active region 18 below second semiconductor device 38. A semiconductor assembly formed in accordance with an embodiment of the present invention may include a fully-depleted area and a partially-depleted area on the same wafer. A fully-depleted area leads to a reduced source/drain capacitance and a higher speed device while a partially-depleted area may be easier to control during manufacturing and operation. First semiconductor device 36 may also have more digital technology advantages, while second semiconductor device 38 may have more analog technology advantages and may have higher precision and be more suited toward increased power applications than first semiconductor device 36.

The ability to manufacture a semiconductor assembly having semiconductor devices with different characteristics and suitable for varying technologies and applications can enable a manufacturer to save time and expense in manufacturing semiconductor technology for a particular technology. For example, it may allow single chip solutions where dual chips may have been needed in previous cases. It may also eliminate design complexity and improve power and performance tradeoffs.

Gate dielectrics 40 are disposed upon portions of active region 18 and serve to insulate gate electrodes 42 from active region 18. Gate dielectrics 40 may be formed by any of a variety of techniques known to those of ordinary skill in the art. Gate dielectrics 40 may be composed of any appropriate type of insulating material, such as silicon dioxide, nitride oxide or tantalum pentaoxide, and may have a thickness of approximately two nanometers.

Disposed upon each gate dielectric 40 are gate electrodes 42. Gate electrodes 42 may be formed upon gate dielectrics 40 by any of a variety of techniques known to those skilled in the art, such as a photoresist and etching process. Gate electrodes 42 may be composed of any appropriate conducting material, such as polycrystalline silicon, and may have a thickness of approximately one hundred twenty nanometers.

Semiconductor assembly 10 also includes spacers 46, silicide portions 54 and body contacts 52, all formed using any of a variety of techniques known to one of ordinary skill in the art.

Standard processing steps are undertaken to complete the manufacture of semiconductor assembly 10. Such processing steps may include the formation of additional layers, contacts, dielectric portions, silicide portions, spacers and other layers and/or structures known to those skilled in the art. Appropriate metal interconnections are formed and passivation is undertaken. Other appropriate methods or steps may be performed to complete the manufacture of semiconductor assembly 10.

FIG. 7 illustrates a semiconductor assembly 70 at one stage of a manufacturing process, in accordance with an embodiment of the present invention. Semiconductor assembly 70 includes first and second device regions 72 and 74, respectively. First and second device regions 72 and 74 are formed in a similar manner to first and second device regions 26 and 27 of FIG. 1. This embodiment, however, illustrates a semiconductor assembly 70 incorporating bipolar technology.

Semiconductor device components are formed at first and second device regions 72 and 74. For example, first and second device regions 72 and 74 both include an emitter structure 76, a dielectric layer 78 and an emitter contact 80. In this embodiment, emitter structure 76 comprises a polysilicon material and is formed using techniques known to one skilled in the art. Device regions 72 and 74 also include a base layer 82 comprising an in situ doped or implanted silicon germanium or any other material containing silicon, such as silicon germanium carbon or silicon itself.

Semiconductor assembly also includes an active region 86 formed adjacent a buried layer 88. Active region 86 may be either a lightly-doped or undoped region. Buried layer 88 is formed using any of a variety of techniques known to those skilled in the art. In the illustrated embodiment, buried layer 88 is an N+buried collector doped with arsenic; however, in other embodiments buried layer 88 may be of another type, such as a P-type buried collector doped with dopants such as boron or indium. Other embodiments may not include a buried layer 88. Buried layer is formed adjacent an oxide layer 90 formed on a wafer 92.

Deep trench isolation structures 84 are formed adjacent portions of active region 86. Deep trench isolation structures 84 provide isolation between elements of semiconductor assembly 70. Shallow trench isolation structures 83 are formed adjacent portions of active region 86. During the formation of shallow trench isolation structures 83, openings are formed for the subsequent formation of components of semiconductor devices for semiconductor assembly 70. This process is similar to that described with respect to semiconductor assembly 10 of FIGS. 1-6. One such opening becomes first device region 72 where components of a semiconductor device are formed, as discussed above. Other embodiments of the present invention may include other semiconductor device components formed within such an opening. For example, in some embodiments a collector contact may be formed at such an opening.

Semiconductor assembly 70 also includes base contacts 94, collector contacts 96, silicide portions 97, sinker implant regions 98 and spacers 99, all formed in accordance with techniques known to one of ordinary skill in the art.

Semiconductor assembly 70 includes many similar advantages to semiconductor 10 of FIGS. 1-6. For example, because the depth of active region 86 below first device region 72 is smaller than the depth of active region 86 below second device region 74, electric current flowing through components at first device region 72 will flow at a higher speed than current flowing through components at second device region 74. Components at first device region 72 make up a semiconductor device having a lower voltage and less capacitance than the semiconductor device made up of components at second device region 74. The ability to manufacture a semiconductor assembly having semiconductor devices with different characteristics and suitable for varying technologies and applications can save manufacturing time and expense.

Standard processing steps may be undertaken to complete the manufacture of semiconductor assembly 70. Such processing steps may include the formation of additional layers, contacts, dielectric portions, silicide portions, spacers and other layers and/or structures known to those skilled in the art. Appropriate metal interconnections may be formed and passivation may be undertaken. Other appropriate methods or steps may be performed to complete the manufacture of semiconductor assembly 70.

The illustrated embodiments incorporate embodiments of the invention in a MOSFET and a bipolar technology. Particular embodiments of the present invention may be incorporated into other semiconductor technologies, such as bipolar complementary metal oxide semiconductor (BiCMOS) and complementary bipolar complementary metal oxide semiconductor (CBiCMOS) that utilize shallow trench isolation as well. Other technologies known to those of ordinary skill in the art may utilize particular embodiments of the present invention as well.

Although particular configurations and methods have been illustrated for particular embodiments of the present invention, other embodiments may include other configurations and/or methods. The present invention has been described in detail; however, various changes and modifications may be suggested to one skilled in the art. It is intended that the present invention encompass such changes and modifications as falling within the scope of the appended claims.

What is claimed is:

1. A method for manufacturing a semiconductor assembly, comprising:
forming an active region of a semiconductor substrate;
removing at least part of the active region to form a shallow trench opening;
forming a dielectric layer proximate the active region at least partially within the shallow trench opening; and
removing at least part of the dielectric layer to form a first device region.

2. The method of claim 1, further comprising forming a first semiconductor device at the first device region, the first semiconductor device operable to facilitate the flow of electric current through the assembly.

3. The method of claim 1, further comprising forming a component of a first semiconductor device at the first device region, the component operable to facilitate the flow of electric current through the assembly.

4. The method of claim 2, further comprising forming a second semiconductor device at a second device region, wherein a depth of an area of the active region below the second device region is greater than a depth of an area of the active region below the first device region.

5. The method of claim 3, further comprising forming a component of a second semiconductor device at a second device region, wherein a depth of an area of the active region below the second device region is greater than a depth of an area of the active region below the first device region.

6. The method of claim 4, wherein the first and second semiconductor devices comprise a metal oxide semiconductor field effect transistor (MOSFET) technology.

7. The method of claim 4, wherein the first and second semiconductor devices comprise a bipolar technology.

8. The method of claim 1, wherein the first device region has a depth of approximately 3,000 to 10,000 angstroms.

9. The method of claim 1, wherein removing at least part of the dielectric layer comprises forming a shallow trench isolation structure adjacent at least a portion of the active region.

10. The method of claim 1, further comprising forming a deep trench isolation structure adjacent at least a portion of the active region.

11. The method of claim 1, further comprising forming an oxide layer adjacent at least a portion of the active region.

12. The method of claim 1, further comprising forming a buried layer adjacent at least a portion of the active region.

13. A semiconductor assembly, comprising:
an active region of a semiconductor substrate;
a shallow trench isolation structure adjacent at least a portion of the active region;
a first device region adjacent at least a portion of the shallow trench isolation structure; and
wherein the first device region has a depth approximately equal to a depth of the shallow trench isolation structure.

14. The semiconductor assembly of claim 13, further comprising a first semiconductor device at the first device region, the first semiconductor device operable to facilitate the flow of electric current through the assembly.

15. The semiconductor assembly of claim 13, further comprising a component of a first semiconductor device at the first device region, the component operable to facilitate the flow of electric current through the assembly.

16. The semiconductor assembly of claim 14, further comprising a second semiconductor device at a second device region, wherein a depth of an area of the active region below the second device region is greater than a depth of an area of the active region below the first device region.

17. The semiconductor assembly of claim 15, further comprising a component of a second semiconductor device at a second device region, wherein a depth of an area of the active region below the second device region is greater than a depth of an area of the active region below the first device region.

18. The semiconductor assembly of claim 16, wherein the first and second semiconductor devices comprise a metal oxide semiconductor field effect transistor (MOSFET) technology.

19. The semiconductor assembly of claim 16, wherein the first and second semiconductor devices comprise a bipolar technology.

20. The semiconductor assembly of claim 13, wherein the first device region has a depth of approximately 3,000 to 10,000 angstroms.

21. The semiconductor assembly of claim 13, further comprising a deep trench isolation structure adjacent at least a portion of the active region.

22. The semiconductor assembly of claim 13, further comprising an oxide layer adjacent at least a portion of the active region.

23. The semiconductor assembly of claim 13, further comprising a buried layer adjacent at least a portion of the active region.
